(19) United States
(12) Patent Application Publication
(10) Pub. No.: US 2013/0168628 A1
(43) Pub. Date: Jul. 4, 2013

(54) VARIABLE RESISTANCE MEMORY DEVICE AND METHOD FOR FABRICATING THE SAME

(71) Applicant: Sang Min HWANG, Gyeonggi-do (KR)

(72) Inventor: Sang Min HWANG, Gyeonggi-do (KR)

(21) Appl. No.: 13/595,660

(22) Filed: Aug. 27, 2012

(30) Foreign Application Priority Data
Dec. 28, 2011 (KR) 10-2011-0145055

(51) Int. Cl. H01L 45/00

(52) U.S. Cl. 257/1; 438/382; 438/3; 257/E45.002

(57) ABSTRACT

A variable resistance memory device includes a first trench extending in a first direction formed in a first insulation layer, a first conductive layer in the first trench, a protective layer over the first conductive layer in the first trench, a second insulation layer over the first insulation layer and the protective layer, a second trench formed in the second insulation layer and extending in a second direction that crosses the first direction, a gap formed in the protective layer exposing the first conductive layer at an intersection between the first trench and the second trench, a variable resistance layer positioned in the gap and coupled to the first conductive layer, and a second conductive layer formed in the second trench and coupled to the variable resistance layer.

### CROSS-REFERENCE TO RELATED APPLICATIONS

The present application claims priority of Korean Patent Application No. 10-2011-0145055, filed on Dec. 28, 2011, which is incorporated herein by reference in its entirety.

### BACKGROUND

1. Field

Exemplary embodiments of the present invention relate to a variable resistance memory device and a method for fabricating the same, and more particularly, to a variable resistance memory device having a cross point cell array structure and a method for fabricating the same.

2. Description of the Related Art

A variable resistance memory device is a device that has a resistance that is varied according to an external stimulus and the resistance of the variable resistance memory device switches between at least two different resistance states to store data. Variable resistance memory devices include ReRAM (Resistive Random Access Memory), PCRAM (Phase Change RAM), SU-RAM (Spin Transfer Torque-RAM), and so on.

Among them, ReRAM has a structure including a variable resistance layer and electrodes formed over and under the variable resistance layer. The variable resistance layer may be formed of a perovskite-based material or transition metal oxide. In addition, a filament current path may form in the variable resistance layer or disappear according to a voltage applied to the electrodes. Therefore, when the filament current path is formed, the resistance of the variable resistance layer decreases, and when the filament current path disappears, the resistance of the variable resistance layer increases. When the variable resistance layer switches from a high-resistance state to a low-resistance state, the operation is referred to as a set operation, and when the variable resistance layer switches from the low-resistance state to the high-resistance state, the operation is referred to as a reset operation.

Further, a cross point cell array structure may be used to increase the integration degree of a variable resistance memory device. Hereafter, a conventional method for fabricating a variable resistance memory device having the cross point cell array structure will be described.

FIG. 1 is a plan view illustrating the layout of a cross point cell array structure. FIG. 2 is a cross-sectional view illustrating a conventional variable resistance memory device and a method for fabricating the same.

Referring to FIGS. 1 and 2, a plurality of memory cells MC are arranged at respective intersections between a plurality of bit lines BL and a plurality of word lines WL. Here, each memory cell MC is coupled to a bit line BL or word line WL through a bottom electrode BE, and the memory cell is also coupled to a word line WL or bit line BL through a top electrode TE.

In accordance with the conventional variable resistance memory device, the bottom electrode BE, the memory cell MC, and the top electrode TE are individually patterned and formed. Therefore, a misalignment may occur between the upper and lower layers. Accordingly, contact resistance may rapidly increase. Furthermore, since a plurality of mask processes are repeated, the fabrication process is complex, and the fabrication cost increases.

### SUMMARY

An embodiment of the present invention is directed to a variable resistance memory device and a method for fabricating the same, which is capable of simplifying a fabrication process of a variable resistance memory device having a cross point cell array structure, reducing a fabrication cost, and preventing a mask pattern misalignment.

In accordance with an embodiment of the present invention, a variable resistance memory device includes: a first trench extending in a first direction formed in a first insulation layer; a first conductive layer in the first trench; a protective layer over the first conductive layer in the first trench; a second insulation layer over the first insulation layer and the protective layer; a second trench formed in the second insulation layer and extending in a second direction that crosses the first direction; a gap formed in the protective layer exposing the first conductive layer at an intersection between the first trench and the second trench; a variable resistance layer positioned in the gap and coupled to the first conductive layer; and a second conductive layer formed in the second trench and coupled to the variable resistance layer.

In accordance with another embodiment of the present invention, a method for fabricating a variable resistance memory device includes: forming a first trench extending in a first direction by selectively etching a first insulation layer; forming a first conductive layer in the first trench; forming a protective layer over the first conductive layer in the first trench; forming a second insulation layer over the first insulation layer including the protective layer formed therein; forming a second trench exposing the protective layer and extending in a second direction that crosses the first direction by selectively etching the second insulation layer; removing the protective layer exposed by the formation of the second trench to form a gap in the protective layer; forming a variable resistance layer in the gap in the protective layer; and forming a second conductive layer in the second trench.

In accordance with yet another embodiment of the present invention, a method for fabricating a variable resistance memory device includes: forming a first trench extending in a first direction by selectively etching a first insulation layer; forming a first conductive layer in the first trench; forming a first protective layer over the first conductive layer in the first trench; forming a second insulation layer over the first insulation layer including the first protective layer formed therein; forming a second trench exposing the first protective layer and extending in a second direction that crosses the first trench by selectively etching the second insulation layer; removing the first protective layer exposed by the formation of the second trench to form a gap in the first protective layer; forming a first variable resistance layer in the gap in the first protection layer; forming a second conductive layer in the second trench; forming a second protective layer over the second conductive layer in the second trench; forming a third insulation layer over the second protective layer and the second insulation layer formed therein; forming a third trench exposing the second protective layer and extending in the first direction by selectively etching the third insulation layer; removing the second protective layer exposed by the formation of the third trench to form a gap in the second protective layer; forming a second variable resistance layer in the gap in the second protective layer; and forming a third conductive layer in the third trench.

### BRIEF DESCRIPTION OF THE DRAWINGS

FIG. 1 is a plan view illustrating the layout of a cross point cell array structure.

FIG. 2 is a cross-sectional view illustrating a conventional variable resistance memory device and a method for fabricating the same.

FIG. 3 is a cross-sectional view illustrating a memory cell arrangement of a variable resistance memory device in accordance with an embodiment of the present invention.

FIGS. 4A and 4B to 16A and 16B are cross-sectional views illustrating the variable resistance memory device and a method for fabricating the same in accordance with the embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

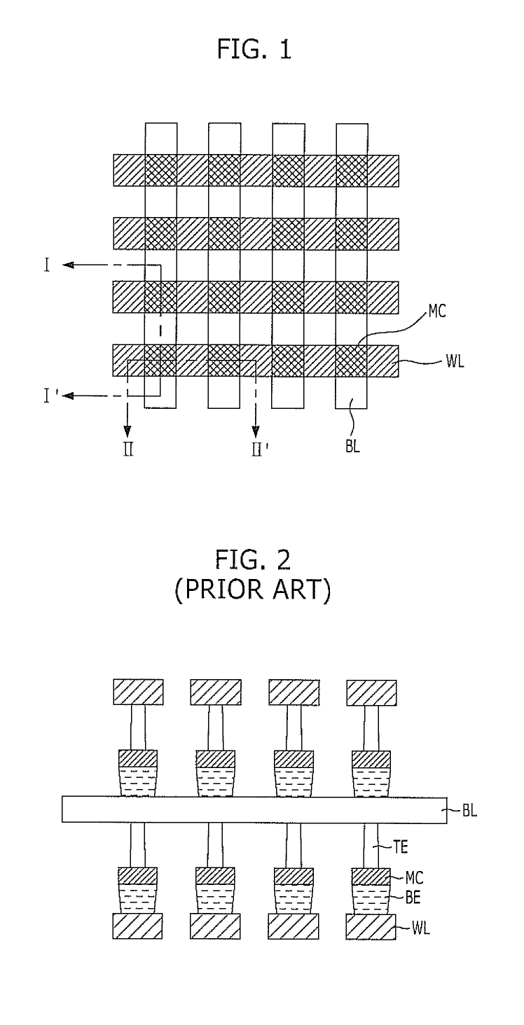

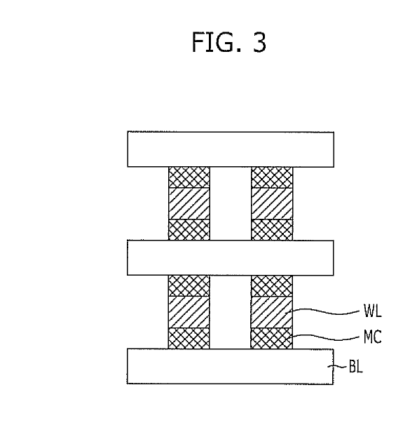

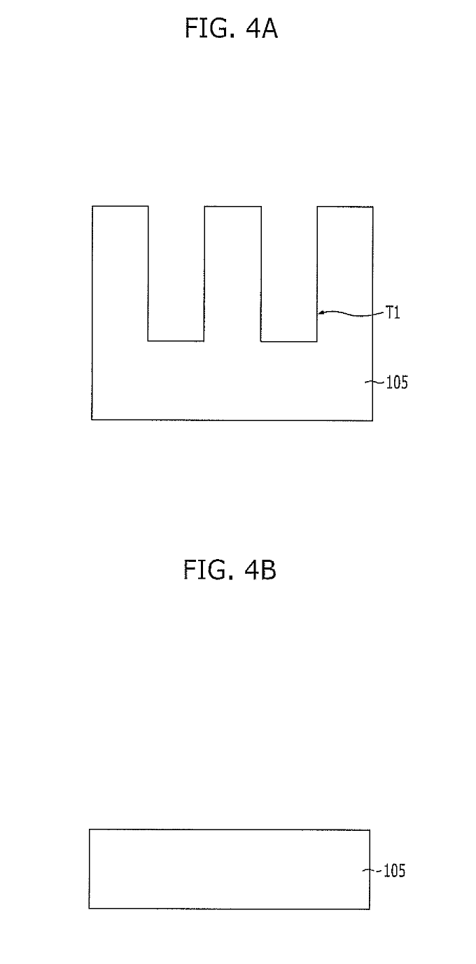

FIG. 1 is a plan view illustrating the layout of a cross point cell array structure. FIG. 3 is a cross-sectional view illustrating a memory cell arrangement of a variable resistance memory device in accordance with an embodiment of the present invention. FIGS. 4A and 4B to 16A and 16B are cross-sectional views illustrating the variable resistance memory device and a method for fabricating the same in accordance with the embodiment of the present invention. Here, FIGS. 4A to 16A illustrate cross-sections taken along a line I-I′ of FIG. 1, and FIGS. 4B to 16B illustrate cross-sections taken along a line II-II′ of FIG. 1.

Referring to FIGS. 4A and 4B, a first insulation layer 105 is formed over a substrate (not illustrated) having a lower structure. The first insulation layer 105 may include one or more oxide-based materials from the group consisting of silicon oxide (SiO₂), TEOS (Tetra Ethyl Ortho Silicate), BPSG (Boron Phosphorus Silicate Glass), BSG (Boron Silicate Glass), PSG (Phosphorus Silicate Glass), FSG (Fluorinated Silicate Glass), and SOG (Spin On Glass). Although not illustrated, the substrate may include peripheral circuits for driving the variable resistance memory device.

A plurality of first trenches T1 are formed by etching the first insulation layer 105 using a mask pattern (not illustrated) as an etch mask. The mask pattern may have a line shape extending in the II-II′ direction of FIG. 1. The plurality of first trenches T1 may be arranged in parallel to each other.

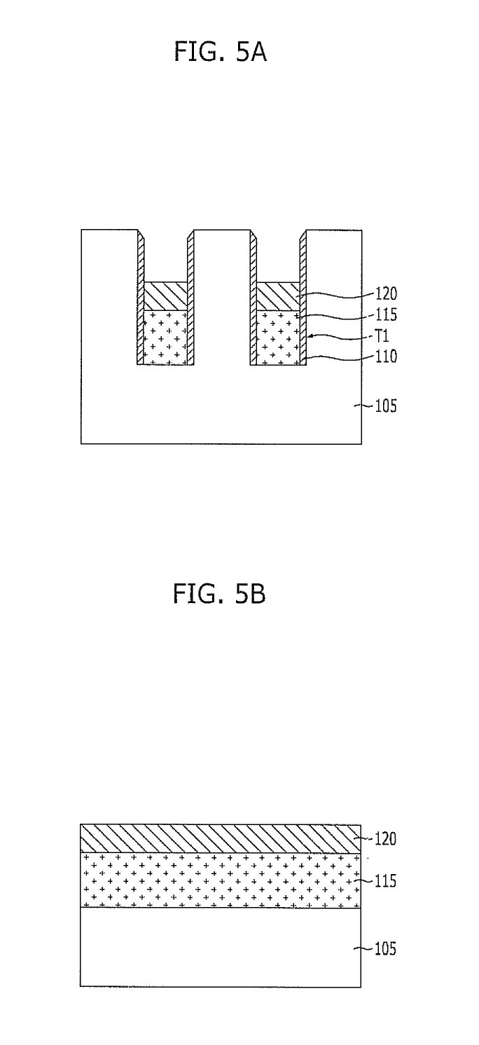

Referring to FIGS. 5A and 5B, a first spacer 110 is formed on sidewalls of each trench T1. The first spacer 110 serves to protect the first trench T1 during a subsequent etch-back process or the like The first spacer 110 may be formed by the following process: depositing a nitride-based material on the first insulation layer 105 having the first trench T1 formed therein, and performing a blanket etch process.

A first conductive line 115 is subsequently buried in the first trench T1. The first conductive line 115 may be formed by the following process: depositing a conductive material, for example, tungsten (W) or aluminum (Al), in the first trench T1 by chemical vapor deposition (CVD) or the like, and subsequently recessing the conductive material by an etch-back process or the like. The recess depth may be decided in consideration of the thicknesses of a first electrode, a first variable resistance layer, and a second electrode, which will be described below. The first conductive line 115 may include a bit line (refer to BL of FIG. 3) or word line (refer to WL of FIG. 3).

A first electrode 120 is formed over the first conductive line 115. The first electrode 120 may be formed by the following process: depositing a conductive material, for example, titanium nitride (TIN), and subsequently recessing the conductive material through an etch-back process or the like.

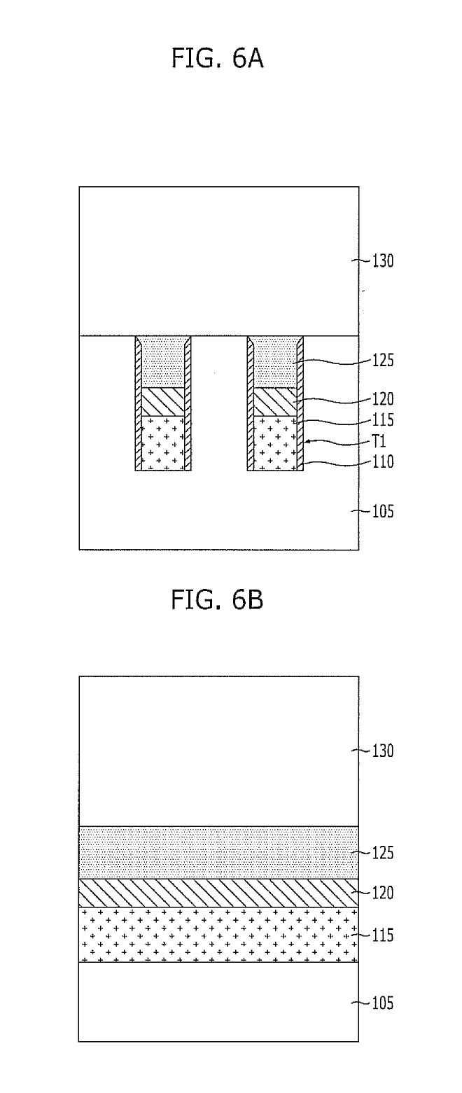

Referring to FIGS. 6A to 6B, a first protective layer 125 is formed over the first electrode 120. The first protective layer 125 may be formed by the following process: depositing a material having an etching selectivity with the first insulation layer 105, for example, a nitride-based material, to such a thickness as to fill the first trench T1 having the first electrode 120 formed therein, and performing a planarization process such as chemical mechanical polishing (CMP) until the top surface of the first insulation layer 105 is exposed. The first protective layer 125 protects the first electrode 120 and serves as an etch stop layer during a subsequent etch kocess for forming second trenches.

A second insulation layer 130 is formed over the first insulation layer 105 including the first protective layer 125. The second insulation layer 130 may include one or more oxide-based materials from the group consisting of SiO₂, TEOS, BPSG, BSG, PSG, FSG, and SOG.

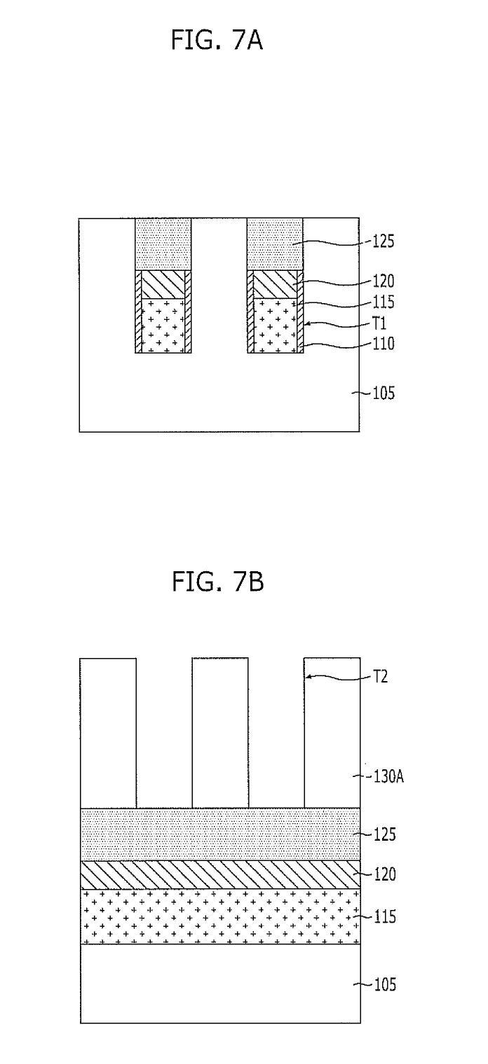

Referring to FIGS. 7A and 7B, a plurality of second trenches T2 are formed by etching the second insulation layer 130 using a mask pattern (not illustrated) as an etch mask. The mask pattern may have a line shape extending in the I-I′ direction of FIG. 1. The plurality of second trenches T2 may be arranged in parallel to each other. The second insulation layer 130 remaining after this process is referred to as a second insulation layer pattern 130A.

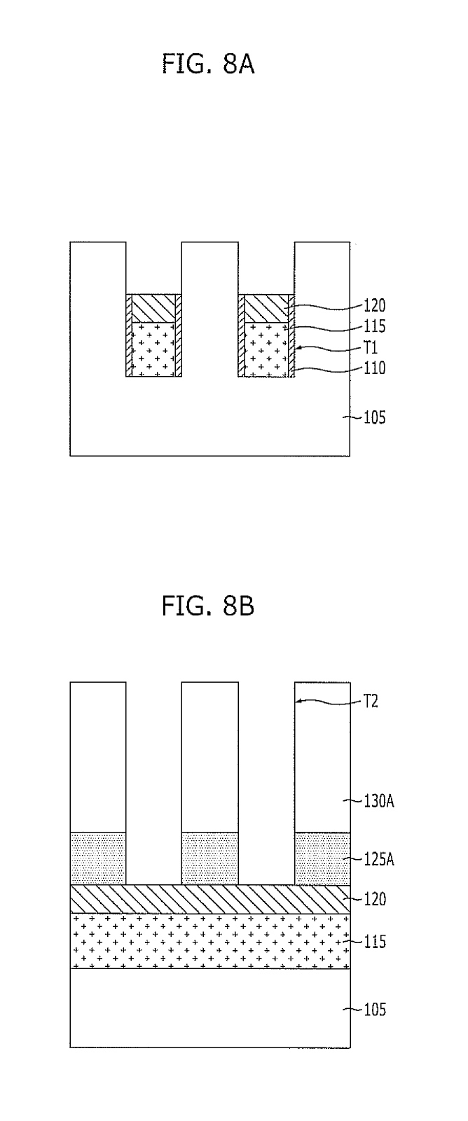

Referring to FIGS. 8A and 8B, the first protective layer 125 exposed by the formation of the second trenches T2 is removed. More specifically, the first protective layer 125 is removed at intersections between the second trenches T2 extending in the I-I′ direction of FIG. 1 and the first trenches T1 extending in the II-II′ direction of FIG. 1. For example, the first protective layer 125 may be selectively removed by using an etching selectivity between the first protective layer 125 and the first insulation layer 105. During this process, the first spacer 110 formed above the first electrode 120 may also be removed. As the result of this process, the first electrode 120 is exposed at the intersections between the first trenches T1 and the second trenches T2. Meanwhile, the first protective layer 125 remaining after this process is referred to as a first protective layer pattern 125A.

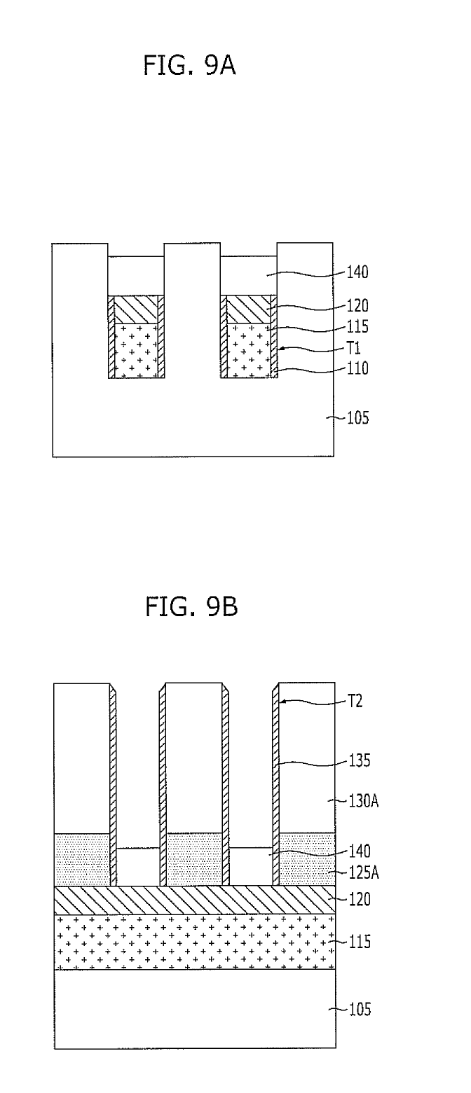

Referring to FIGS. 9A and 9B, a second spacer 135 is formed on sidewalk of each second trench T2. The second spacer 135 serves to protect the second trench T2 during a subsequent etch-back process or the like. The second spacer 135 may be formed by the following process: depositing a nitride-based material on the second insulation layer pattern 130A including the second trench T2 and subsequently performing a blanket etch process.

A first variable resistance layer 140 is formed over the first electrode 120. The first variable resistance layer 140 may include a structure whose electric resistance is varied by migration of oxygen vacancies or ions or phase change of a material, or a magnetic tunnel junction (MTJ) structure whose electric resistance is varied by a magnetic field, or spin transfer torque (STT).

Here, the structure whose electric resistance is varied by migration of oxygen vacancies or ions may include perovskite-based materials such as STO (SrTiO₃), BTO (BaTiO₃), and PCMO (Pr₁₋ₓCaₓMnO₃) or binary oxides including transition metal oxides (TMO) such as titanium oxide (TiO₂), hafnium oxide (HfO₂), zirconium oxide (ZrO₂), aluminum oxide (Al₂O₃), tantalum oxide (Ta₂O₅), niobium oxide (Nb₂O₅), cobalt oxide (Co₃O₄), nickel oxide (NiO), tungsten oxide (WO₃), and lanthanum oxide (La₂O₃). The structure whose electric resistance is varied by phase change of a material may include a material that is changed into a crystalline state or amorphous state by heat, for example, a chalcogenide-based material such as GST (GeSbTe) in which germanium, antimony, and tellurium are combined at a designated ratio.

Furthermore, the MTJ structure may include a magnetic free layer, a magnetic fixed layer, and a barrier layer interposed therebetween. The magnetic free layer and the magnetic fixed layer may include a ferromagnetic substance, for example, iron (Fe), nickel (Ni), Co, gadolinium (Gd), dysprosium (Dy), or a compound thereof, and the barrier layer may include magnesium oxide (MgO), Al₂O₃, HfO₂, ZrO₃, and SiO₂.

Although not illustrated, a selection element coupled to the top or bottom of the first variable resistance layer 140, for example, a transistor or diode may be additionally formed, if necessary. Furthermore, the upper surface of the first variable resistance layer 140 is set to a lower height than the upper surface of the first insulation layer 105, and the first variable resistance layer 140 may have an island shape arranged in a matrix form, when seen from the top.

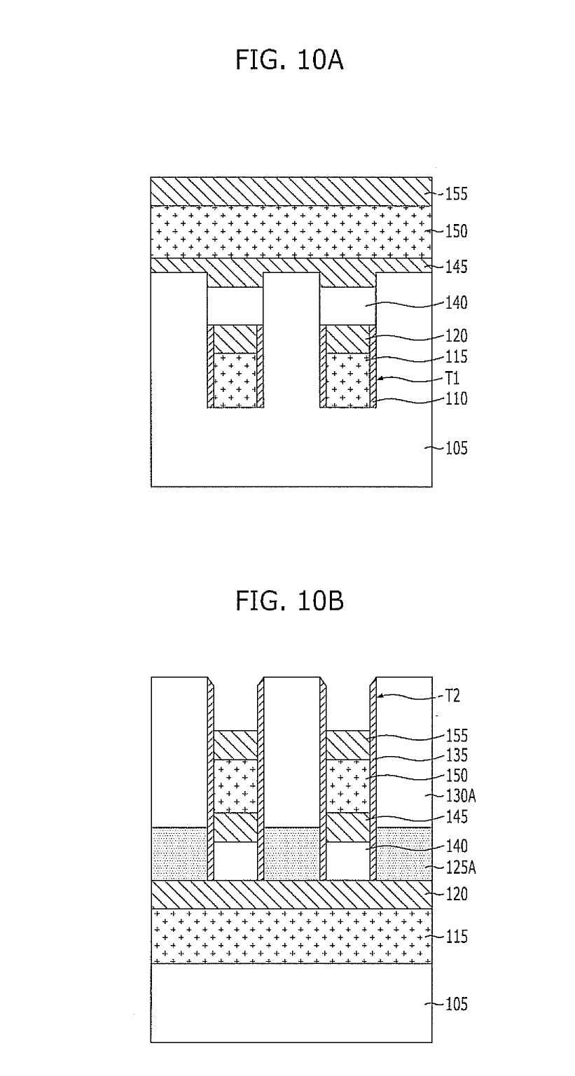

Referring to FIGS. 10A and 10B, a second electrode 145 is formed in the second trench T2. The second electrode 145 may be formed by the following process: depositing a conductive material, for example, TiN, in the second trench T2 and subsequently recessing the conductive material through an etch-back process or the like.

A second conductive line 150 is formed over the second electrode 145. The second conductive line 150 may be formed by the following process: depositing a conductive material, for example, W or Al, by CVD or the like and subsequently recessing the conductive material through an etch-back process or the like. For example, the recess depth may be decided in consideration of the thicknesses of a third electrode, a second variable resistance layer, and a fourth electrode, which will be described below, and the second conductive layer 150 may include a word line (refer to WL of FIG. 3) or bit line (BL of FIG. 3).

The third electrode 155 is formed over the second conductive line 150. The third electrode 155 may be formed by the following process: depositing a conductive material, for example, TiN, and subsequently recessing the conductive material through an etch-back process or the like.

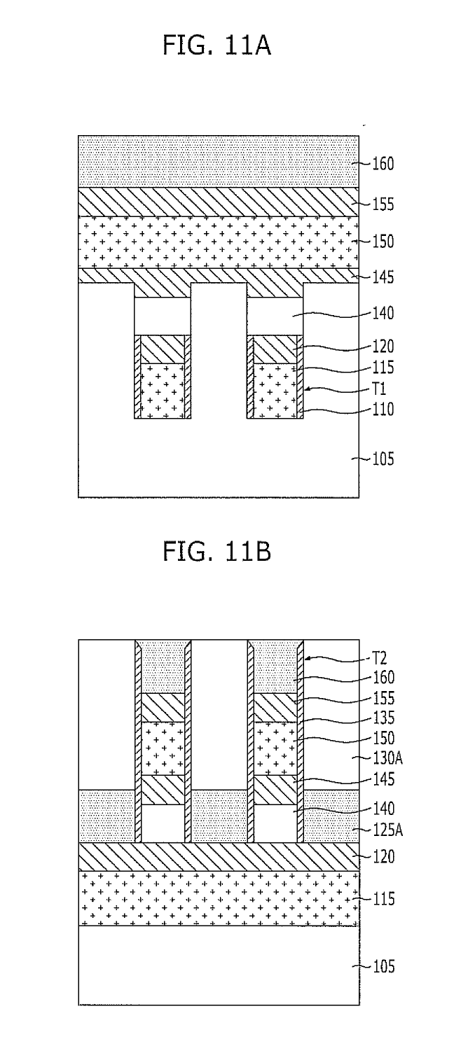

Referring to FIGS. 11A and 11B, a second protective layer 160 is formed over the third electrode 155. The second protective layer 160 may be formed by the following process: depositing a material having an etching selectivity with the second insulation layer pattern 130A, for example, a nitride-based material, to such a thickness as to fill the second trench T2 having the third electrode 155 formed therein, and performing a planarization process such as CMP until the top surface of the second insulation layer pattern 130A is exposed. The second protective layer 160 protects the third electrode 155 and serves as an etch stop layer during a subsequent etching process for forming third trenches, which is to be described below.

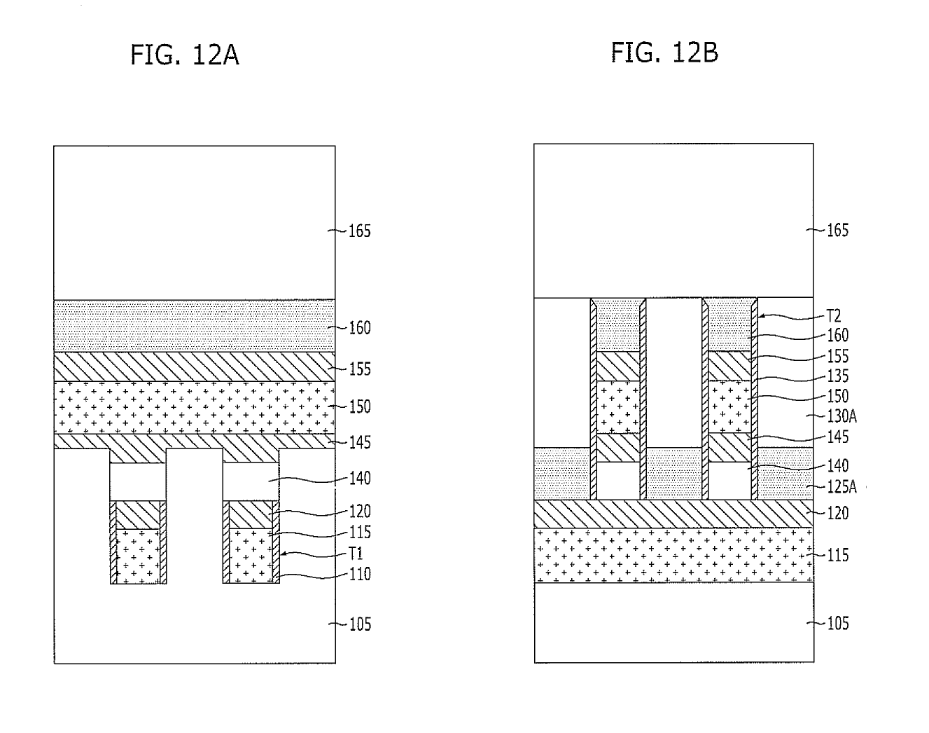

Referring to FIGS. 12A and 12B, a third insulation layer 165 is formed over the second protective layer 160 and the second insulation layer pattern 130A. The third insulation layer 165 may include one or more oxide-based materials from the group consisting of SiO₂, TEOS, BPSG, BSG, PSG, FSG, and SOG.

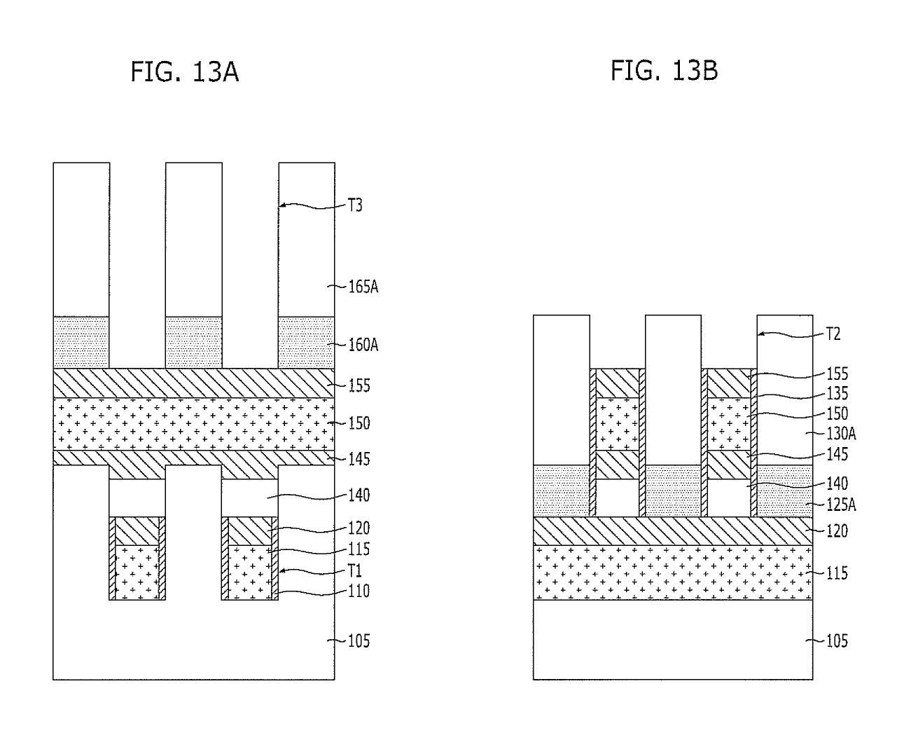

Referring to FIGS. 13A and 13B, a plurality of trenches T3 are formed by etching the third insulation layer 165 using a mask pattern (not illustrated) as an etch mask. The mask pattern may have a line shape extending in the same direction as the first trenches T1. The plurality of trenches T3 may be arranged in parallel to each other.

The second protective layer 160 exposed by the formation of the third trenches T3 is removed. More specifically, the second protective layer 160 is removed at intersections between the second trenches T2 extending in the direction of FIG. 1 and the third trenches T3 extending in the II-II′ direction of FIG. 1. For example, the second protective layer 160 may be selectively removed by using an etching selectivity between the second protective layer 160 and the second insulation layer pattern 130A. During this process, the second spacer 135 formed above the third electrode 155 may also be removed. As the result of this process, the third electrode 155 is exposed at the intersections between the second trenches T2 and the third trenches T3. Meanwhile, the second protective layer 160 and the third insulation layer 165, which remain after this process, are referred to as a second protective layer pattern 160A and a third insulation layer pattern 165A, respectively.

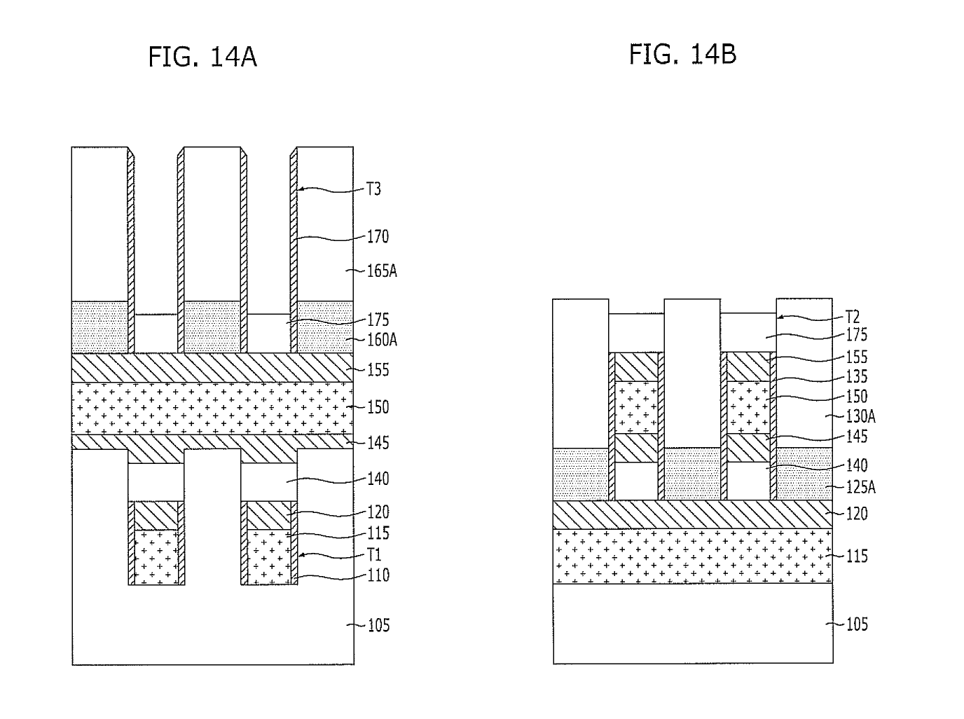

Referring to FIGS. 14A and 14B, a third spacer 170 is formed on sidewalls of each third trench T3. The third spacer 170 serves to protect the third trench T3 during a subsequent etch-back process or the like. The third spacer 170 may be formed by the following process: depositing a nitride-based material on the third insulation layer 165A including the third trench T3 and subsequently performing a blanket etch process.

A second variable resistance layer 175 is formed over the third electrode 155. The second variable resistance layer 175 may include a structure whose electric resistance is varied by migration of oxygen vacancies or ions or phase change of a material, or an MTJ structure whose electric resistance is varied by a magnetic field, or STT. The second variable resistance layer 175 may be formed of the same material as the first variable resistance layer 140.

Although not illustrated, a selection element coupled to the top or bottom of the second variable resistance layer 175, for example, a transistor or diode may be additionally formed, if necessary. The upper surface of the second variable resistance layer 175 is set to a lower height than the upper surface of the second insulation layer pattern 130A; the second variable resistance layer 175 may have an island shape arranged in a matrix form, when seen from the top.

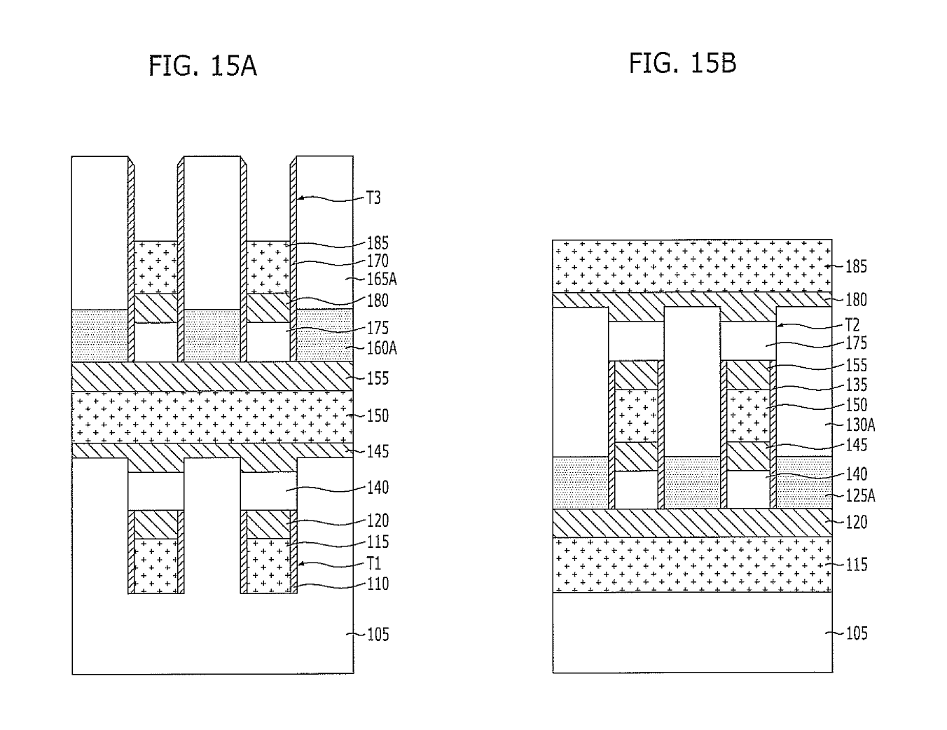

Referring to FIGS. 15A and 15B, a fourth electrode 180 is formed in the third trench T3. The fourth electrode 180 may be formed by the following process: depositing a conductive material, for example, TiN, in the third trench T3 and subsequently recessing the conductive material through an etch-back process or the like.

A third conductive line 185 is formed over the fourth electrode 180. The third conductive line 185 may be formed by the following process: depositing a conductive material, for example, W or Al, by CVD or the like, and subsequently recessing the conductive material through an etch-back process or the like. For example, the third conductive line 185 may include a bit line (BL of FIG. 3) or word line (WL of FIG. 3).

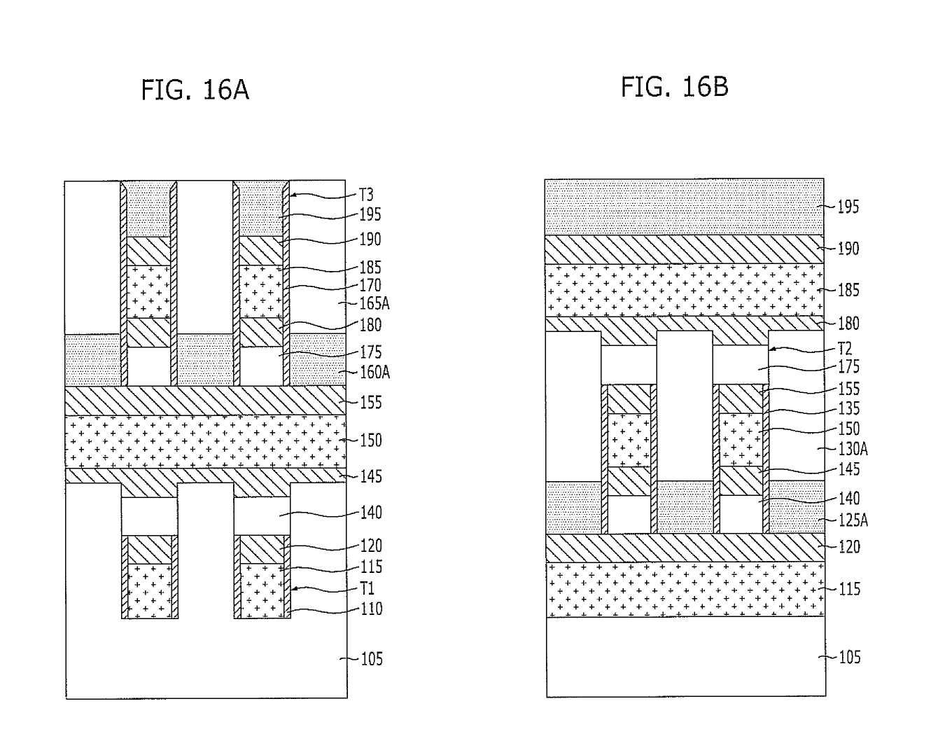

Referring to FIGS. 16A and 16B, a fifth electrode 190 is formed over the third conductive line 185. The fifth electrode 190 may be formed by the following process: depositing a conductive material, for example, TiN, and subsequently recessing the conductive material through an etch-back process or the like.

A third protective layer 195 is formed over the fifth electrode 190. The protective layer 195 may be formed by the following process: depositing a material having an etching selectivity with the third insulation layer pattern 165A, for example, a nitride-based material, to such a thickness as to fill the third trench T3 having the fifth electrode 190 formed therein, and performing a planarization process such as CMP until the top surface of the third insulation layer pattern 165A is exposed. The third protective layer 195 serves to protect the fifth electrode 190 and serves as an etch stop layer during a subsequent etching process.

The variable resistance memory device in accordance with the embodiment of the present invention, as illustrated in FIGS. 16A and 16B, may be fabricated by the above-described fabrication method.

Referring to FIGS. 16A and 16B, the variable resistance memory device in accordance with the embodiment of the present invention includes the first trench T1 extending in a first direction in the first insulation layer 105, a first conductive layer including the first conductive line 115 and the first electrode 120 formed over the conductive line 115 in the first trench T1, the first protective layer 125 formed over the first conductive layer, the second insulation layer 130 formed over the first insulation layer 105 and the first protective layer 125, the second trench T2 extending in a direction crossing the first trench T1 in the second insulation layer 130, a gap exposing the first conductive layer at the intersection between the first trench T1 and the second trench T2, the first variable resistance layer 140 coupled to the first conductive layer while positioned in the gap, a second conductive layer including the second electrode 145 coupled to the first variable resistance layer 140 while positioned in the second trench T2 and the second conductive layer 150 over the second electrode 145, the first or second spacer 110 or 135 formed on the sidewall of the first or second trench T1 or T2, and a selection element coupled to the top or bottom of the first variable resistance layer 140.

Here, the first protective layer 125 may be formed of a material having an etching selectivity with the first insulation layer 105, and the first variable resistance layer 140 may include a structure whose electric resistance is varied by migration of oxygen vacancies or ions or phase change of a material, or an MTJ structure whose electric resistance is varied by a magnetic field, or STT.

Referring to FIGS. 1 and 3, the above-described fabrication process may be repetitively performed to form multilayered cross point cell array structures. The cross point cell array structure includes a plurality of memory cells MC arranged at the respective intersections between a plurality of bit lines BL parallel to each other and a plurality of word lines WL parallel to each other while crossing the bit lines BL, and a selection element (not illustrated), for example, a transistor or diode may be coupled to the top or bottom of each memory cell MC.

Here, the memory cell MC may include a variable resistance layer, and an electrode (not illustrated) may be additionally interposed between the memory cell MC and a bit line BL or word line WL. Meanwhile, the electrode, the bit line BL, and the word line WL may include conductive materials, for example, metals such as W, Al, Cu, Au, Ag, Pt, Ni, Cr, Co, Ti, Ru, Hf, Zr and metal nitrides TiN, TaN, and WN. Meanwhile, FIG. 3 illustrates that four layers of memory cells MC are stacked. However, the present invention is not limited thereto, and three or less layers or five or more layers of memory cells MC may be stacked.

In accordance with the embodiments of the present invention, the variable resistance layer and the electrodes over and under the variable resistance layer may not be formed by patterning processes using separate mask patterns, but may be buried together with the conductive line in the trench. Accordingly, an increase of contact resistance caused by a misalignment of mask patterns may be prevented. Furthermore, as the number of mask processes is reduced in comparison with the conventional fabrication method, the fabrication process may be simplified, and the fabrication cost may be reduced.

While the present invention has been described with respect to the specific embodiments, it will be apparent to those skilled in the art that various changes and modifications may be made without departing from the spirit and scope of the invention as defined in the following claims.

What is claimed is:

1. A variable resistance memory device comprising:
a first trench extending in a first direction formed in a first insulation layer;
a first conductive layer in the first trench;
a protective layer over the first conductive layer in the first trench;
a second insulation layer over the first insulation layer and the protective layer;
a second trench formed in the second insulation layer and extending in a second direction that crosses the first direction;
a gap formed in the protective layer exposing the first conductive layer at an intersection between the first trench and the second trench;
a variable resistance layer positioned in the gap and coupled to the first conductive layer; and
a second conductive layer formed in the second trench and coupled to the variable resistance layer.

2. The variable resistance memory device of claim 1, wherein the first conductive layer comprises a first conductive line and a first electrode formed over the first conductive line, and
the second conductive layer comprises a second electrode and a second conductive line formed over the second electrode.

3. The variable resistance memory device of claim 1, further comprising a spacer formed on sidewalls of the first or second trench.

4. The variable resistance memory device of claim 1, wherein the protective layer is formed of a material having an etching selectivity with the first insulation layer.

5. The variable resistance memory device of claim 1, wherein the variable resistance layer comprises a structure whose electric resistance is varied by migration of oxygen vacancies or ions or phase change of a material, or a magnetic tunnel junction (MTJ) structure whose electric resistance is varied by a magnetic field, or spin transfer torque (STT).

6. The variable resistance memory device of claim 1, further comprising:
a selection element formed above or below the variable resistance layer and coupled to the variable resistance layer.

7. A method for fabricating a variable resistance memory device, comprising:
forming a first trench extending in a first direction by selectively etching a first insulation layer;
forming a first conductive layer in the first trench;
forming a protective layer over the first conductive layer in the first trench;
forming a second insulation layer over the first insulation layer including the protective layer formed therein;
forming a second trench exposing the protective layer and extending in a second direction that crosses the first direction by selectively etching the second insulation layer;
removing the protective layer exposed by the formation of the second trench to form a gap in the protective layer;
forming a variable resistance layer in the gap in the protective layer; and
forming a second conductive layer in the second trench.

8. The method of claim 7, wherein the first conductive layer comprises a first conductive line and a first electrode formed over the first conductive line, and
the second conductive layer comprises a second electrode and a second conductive line formed over the second electrode.

9. The method of claim 7, further comprising forming a spacer on sidewalls of the first or second trench, after the forming of the first or second trench.

10. The method of claim 7, wherein the protective layer is formed of a material having an etching selectivity with the first insulation layer.

11. The method of claim 7, wherein the variable resistance layer comprises a structure whose electric resistance is varied by migration of oxygen vacancies or ions or phase change of a material, or a magnetic tunnel junction (MTJ) structure whose electric resistance is varied by a magnetic field, or spin transfer torque (STT).

12. The method of claim 7, further comprising forming a selection element above or below the variable resistance layer and coupled to of the variable resistance layer.

13. A method for fabricating a variable resistance memory device, comprising:
forming a first trench extending in a first direction by selectively etching a first insulation layer;
forming a first conductive layer in the first trench;
forming a first protective layer over the first conductive layer in the first trench;
forming a second insulation layer over the first insulation layer including the First protective layer formed therein;
forming a second trench exposing the first protective layer and extending in a second direction that crosses the first trench by selectively etching the second insulation layer;
removing the first protective layer exposed by the formation of the second trench to form a gap in the first protective layer;
forming a first variable resistance layer in the gap in the first protection layer;
forming a second conductive layer in the second trench;
forming a second protective layer over the second conductive layer in the second trench;
forming a third insulation layer over the second protective layer and the second insulation layer formed therein;
forming a third trench exposing the second protective layer and extending in the first direction by selectively etching the third insulation layer;
removing the second protective layer exposed by the formation of the third trench to form a gap in the second protective layer;
forming a second variable resistance layer in the gap in the second protective layer; and
forming a third conductive layer in the third trench.

14. The method of claim 13, wherein the first conductive layer comprises a first conductive line and a first electrode formed over the first conductive line,
the second conductive layer comprises a second electrode, a second conductive line formed over the second electrode, and a third electrode formed over the second conductive line, and
the third conductive layer comprises a fourth electrode, a third conductive line formed over the fourth electrode, and a fifth electrode formed over the third conductive line.

15. The method of claim 13, further comprising forming a spacer on sidewalls of the first, second, or third trench, after the forming of the first, second, or third trench.

16. The method of claim 13, wherein the first protective layer is formed of a material having an etching selectivity with the first insulation layer, and
the second protective layer is formed of a material having an etching selectivity with the second insulation layer.

17. The method of claim 13, wherein the first and second variable resistance layers comprise a structure whose electric resistance is varied by migration of oxygen vacancies or ions or phase change of a material, or a magnetic tunnel junction (MD) structure whose electric resistance is varied by a magnetic field, or spin transfer torque (STT).

18. The method of claim 13, further comprising forming a selection element above or below the variable resistance layer and coupled to the first and second variable resistance layers.
